(19) United States
(12) Patent Application Publication
(10) Pub. No.: US 2025/0366029 A1
(43) Pub. Date: Nov. 27, 2025

(54) THIN-FILM TRANSISTOR AND PREPARATION METHOD THEREFOR, AND MEMORY AND DISPLAY

(71) Applicant: INSTITUTE OF MICROELECTRONICS OF THE CHINESE ACADEMY OF SCIENCES, Beijing (CN)

(72) Inventors: Ming LIU, Beijing (CN); Ling LI, Beijing (CN); Di GENG, Beijing (CN); Xinlv DUAN, Beijing (CN); Congyan LU, Beijing (CN); Nianduan LU, Beijing (CN)

(73) Assignee: INSTITUTE OF MICROELECTRONICS OF THE CHINESE ACADEMY OF SCIENCES, Beijing (CN)

(21) Appl. No.: 18/873,672

(22) PCT Filed: Aug. 31, 2022
(86) PCT No.: PCT/CN2022/116072

§ 371 Date: Dec. 10, 2024

(30) Foreign Application Priority Data
Jun. 10, 2022 (CN) 202210656607.X

(51) Int. Cl. H10D 30/67; H10D 30/01; H10D 86/60

(52) U.S. Cl. CPC H10D 30/6713; H10D 30/0318; H10D 30/6728; H10D 30/6757; H10D 86/60

(57) ABSTRACT

Disclosed are a thin-film transistor and a preparation method therefor, and a memory and a display. The thin-film transistor comprises: a second source/drain layer (2), an insulation layer (3) and a first source/drain layer (1), which are sequentially arranged in a stacked manner; and a gate electrode (5) and a channel layer (4) surrounding the gate electrode (5), which are located in the first source/drain layer (1) and the insulation layer (3), wherein the channel layer (4) is in contact with the first source/drain layer (1) and the second source/drain layer (2); the first source/drain layer (1) comprises a first metal layer (11) and a second metal layer (12), the first metal layer (11) is close to the insulation layer (3), and the second metal layer (12) is away from the insulation layer (3); the material of the first metal layer (11) is a metal with a work function lower than that of molybdenum; and the material of the second metal layer (12) is a metal with a conductivity higher than 3×10⁶ S/m and an oxidation resistance not lower than that of molybdenum. By means of the thin-film transistor of a CAA architecture, the size of the transistor can be reduced, the power consumption of the transistor can be reduced, and the contact performance and the conductivity performance of the transistor can be improved.

### CROSS-REFERENCE TO RELATED PATENT APPLICATIONS

This application claims a priority from the Chinese Patent Application No. 202210656607.X, filed with the Chinese Patent Office on Jun. 10, 2022, entitled “THIN-FILM TRANSISTOR AND PREPARATION METHOD THEREFOR, AND MEMORY AND DISPLAY”, content of which is incorporated herein by reference in its entirety.

### FIELD OF THE INVENTION

The disclosure relates to a thin film transistor, a preparation method therefor, a memory, and a display.

### BACKGROUND OF THE INVENTION

According to Moore's law, integrated circuits continue to develop towards finer dimensions, and advanced fabrication process is one of the cutting-edge nodes of integrated circuit fabrication. Currently, the advanced fabrication process has evolved to nodes of 5/7 nm, which places extremely high demands on further miniaturization of transistor.

The design of a Fin Field Effect Transistor (FinFET), which is one key architecture for the current transistor, can greatly improve circuit control and reduce leakage current, while greatly shortening the gate length of the transistor. However, the FinFET architecture is applicable to a process of 10-22 nm. For processes below 10 nm, such as 7 nm, 5 nm, and 3 nm, it will be limited by the scaling of the width of the FinFET, and cannot ensure high performance and low power consumption while continuing to shrink the size. On the other hand, at present, the source/drain of FinFET also suffers from poor contact performance and poor conductivity.

Therefore, it becomes an urgent problem to be solved how to further reduce the size of the transistor, reduce power consumption of the transistor, improve contact performance and conductivity of the transistor, and meet the requirements of high performance and low power consumption of advanced processes.

### SUMMARY OF THE INVENTION

The present disclosure provides a thin film transistor and a method for preparing the same, a memory, and a display, solving the technical problem of how to further reduce the size of the transistor, reduce power consumption of the transistor, improve contact performance and conductivity of the transistor.

In a first aspect, the present disclosure provides a thin film transistor, including: a second source/drain layer, an insulating layer, and a first source/drain layer stacked in sequence; and a gate and a channel layer surrounding the gate, which are located within the first source/drain layer and the insulating layer, in which the channel layer is in contact with the first source/drain layer and the second source/drain layer, in which the first source/drain layer includes a first metal layer and a second metal layer, the first metal layer is close to the insulating layer, the second metal layer is away from the insulating layer, the material for the first metal layer is a metal with a work function being lower than that of molybdenum, and the material for the second metal layer is a metal with a conductivity being higher than 3×10⁶ S/m and oxidation resistance being not lower than that of molybdenum.

In a second aspect, the present disclosure provides a method for preparing a thin film transistor, including: providing a substrate;

forming in sequence a second source/drain layer, an insulating layer and a first source/drain layer on the substrate, in which the first source/drain layer includes a first metal layer and a second metal layer, the first metal layer is formed on the insulating layer, the second metal layer is formed on the first metal layer, the material for the first metal layer is a metal with a work function being lower than that of molybdenum, and the material for the second metal layer is a metal with a conductivity being higher than 3×10⁶ S/m and an oxidation resistance being not lower than that of molybdenum;

forming a hole extending to the second source/drain layer within the first source/drain layer and the insulating layer;

depositing a channel material on an inner wall of the hole and a surface of the first source/drain layer to form a channel layer; and

depositing a gate material on the channel layer to form a gate.

In a third aspect, the present disclosure provides a memory including a plurality of memory arrays which include the thin film transistor provided in the first aspect.

In a fourth aspect, the present disclosure provides a display including a pixel circuit which includes the thin film transistor provided in the first aspect.

The present disclosure provides a thin film transistor, in which a gate of the thin film transistor passes through a first source/drain layer and an insulating layer, and an annular channel surrounds the gate to form an architecture of Channel All Around, which is referred to as a transistor with CAA architecture. Compared with a transistor with FinFET architecture, the transistor with CAA architecture according to the present disclosure has the following advantages. Firstly, the vertical channel structures, relative to the planar channel structure, reduces the horizontal area occupation of the electrode by stacking source/drain electrodes, which can significantly reduce the size of the transistor and is conducive to reducing the device unit density. The length of the channel is determined by the thickness of the insulating layer, and the miniaturization of the length of the channel is not limited by the lithography process, which is conducive to achieve a smaller length of the channel, thereby improving the width to length ratio of the channel, achieving a larger device current and reducing power consumption. Secondly, the CAA architecture with the annular channel surrounding the gate can greatly increase the contact area between the gate and the channel layer, thereby significantly enhancing gate control ability of the gate on the channel layer and improving current conduction efficiency. Compared with a GAA (Gate All Around) architecture, the CAA architecture also has a larger contact area between the gate and the channel layer. Thirdly, a layered structure is adopted for the first source/drain layer of the thin film transistor, in which the first metal layer close to the insulating layer adopts a metal with a lower work function to improve contact performance. Since a metal with a lower work function usually has weaker oxidation resistance, the second metal layer away from the insulating layer adopts a metal with better conductivity and better oxidation resistance. While protecting the first metal layer from oxidation without reducing contact performance, the resistance of the source/drain metal lead is reduced, and the conductivity of the transistor is improved.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the specific embodiments of the present disclosure are set forth as follows.

### BRIEF DESCRIPTION OF THE DRAWINGS

FIG. 1 is a schematic structural diagram of a thin film transistor according to an embodiment of the present disclosure;

FIG. 2 is a schematic structural diagram of a thin film transistor including a third metal layer according to an embodiment of the present disclosure;

FIG. 3 is a schematic flowchart of a method for preparing a thin film transistor according to an embodiment of the present disclosure; and

FIG. 4 is a schematic diagram of a storage array according to an embodiment of the present disclosure.

Reference signs are denoted as follows:

1. first source/drain layer; 11. first metal layer; 12. second metal layer; 13. third metal layer; 2. second source/drain layer; 21. fourth metal layer; 22. fifth metal layer; 23. sixth metal layer; 3. insulating layer; 4. channel layer; 5. gate; 6. gate dielectric layer; 71. first thin film transistor; 72. second thin film transistor.

### DETAILED DESCRIPTION OF THE INVENTION

In order to enable those skilled in the art to understand the present disclosure more clearly, the technical solutions of the present disclosure will be described in detail through specific embodiments with reference to the accompanying drawings. Throughout the specification, unless otherwise specifically stated, the terms used herein are to be understood as having the meanings commonly used in the art. Thus, unless otherwise defined, all technical and scientific terms used herein have the same meaning as commonly understood by one of ordinary skill in the art to which this disclosure belongs. If there is a contradiction, the present specification preferably takes precedence. Unless otherwise specified, various devices and the like used in the present disclosure may be obtained through market purchase or may be prepared by existing methods.

In the description of the present disclosure, it should be noted that the orientation or position relationship indicated by the terms “center”, “upper”, “lower”, “left”, “right”, “vertical”, “horizontal”, “inner”, “outer” and the like is based on the orientation or position relationship shown in the accompanying drawings, or the orientation or position relationship normally placed when the product is used is merely for ease of description, rather than indicating or implying that the device or element referred to has to have a specific orientation, and is constructed and operated in a specific orientation, and therefore cannot be understood as a limitation to the present disclosure. In addition, the terms “first”, “second”, “third”, and the like are only used to distinguish descriptions, and cannot be understood as indicating or implying relative importance.

In addition, terms such as “horizontal”, “vertical”, and “overhang” do not indicate that a component is required to be absolutely horizontal or suspended, but may be slightly inclined. For example, “horizontal” means that the direction thereof is relatively horizontal relative to “vertical”, and does not indicate that the structure is necessarily completely horizontal, but may be slightly inclined.

Researches show that the reason for poor contact performance and poor conductivity of the source/drain of the transistor is as follows. In order to ensure durability, a metal for the source/drain has better oxidation resistance but higher work function, such as molybdenum (Mo) and titanium nitride (TiN). However, a metal with higher work function suffers from poorer contact performance and poorer conductivity. A metal with a lower work function, such as titanium (Ti), tungsten (W) can improve contact performance and conductivity, but is easily oxidized. After oxidation, contact performance will still deteriorate, and metal resistance will increase.

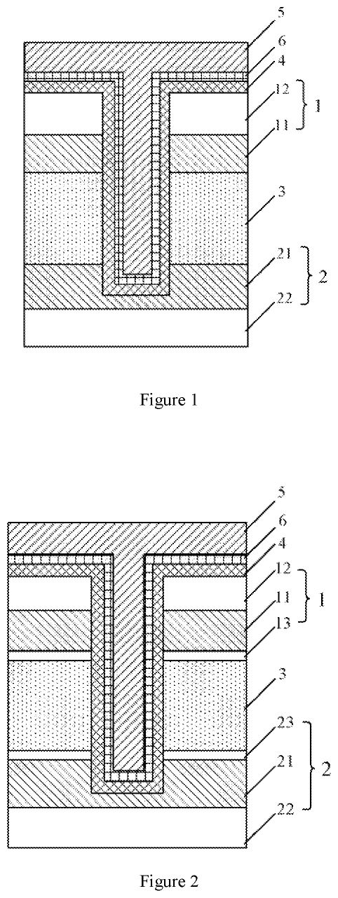

In a first aspect, the present disclosure provides a thin film transistor (TFT), whose structure is shown in FIG. 1, including:

a second source/drain layer 2, an insulating layer 3, and a first source/drain layer 1 stacked in sequence; and

a gate 5 and a channel layer 4 surrounding the gate 5, which are located within the first source/drain layer 1 and the insulating layer 3, in which the channel layer 4 is in contact with the first source/drain layer 1 and the second source/drain layer 2.

Specifically, the TFT transistor provided in this embodiment has a vertical channel structure. For ease of understanding, the first source/drain layer 1 can be regarded as an upper source/drain of the TFT, and the second source/drain layer 2 is regarded as a lower source/drain of the TFT. In actual use, the first source/drain layer 1 can be prepared as a source, and the second source/drain layer 2 can be prepared as a drain. Alternatively, the first source/drain layer 1 may also be prepared as a drain, and the second source/drain layer 2 may be prepared as a source, which is not specifically limited herein.

The gate 5 is of a vertical structure, and the bottom of the gate 5 at least penetrates the first source/drain layer 1 and enters the insulating layer 3. The bottom of the gate 5 can also penetrates the insulating layer 3 and enters the second source/drain layer 2. The shape of the gate 5 may be cylindrical, and the cross-sectional shape may be circular, elliptical or polygonal. The shape of the gate 5 may also be annular, and the cross-sectional shape may be a circular ring, an elliptical ring, or a polygonal ring, which may be determined according to practical requirement. The optional materials for the gate 5 are indium tin oxide (ITO), indium zinc oxide (IZO), or titanium nitride (TiN).

The channel layer 4 is of a vertical channel structure, which is formed around a portion of the gate 5 within the first source/drain layer 1 and the insulating layer 3. Therefore, the TFT transistor according to the present embodiment belongs to a CAA (Channel All Around) architecture in which a vertical channel fully surrounds the gate. The cross-sectional shape of the channel layer 4 may be circular, elliptical or polygonal, and the cross-sectional shape of the channel layer 4 may be the same as or different from the cross-sectional shape of the gate 5.

A preferred shape of the channel layer 4 is a shape with a largest cross-sectional perimeter selected under the premise that the cross-sectional area of the channel layer 4 remains unchanged. In this way, the channel width of the channel layer 4 can be improved, thereby further improving the width to length ratio of the channel, and facilitating the improvement of a saturation current of the thin film transistor.

Materials for the channel layer 4 may be Indium Gallium Zinc Oxide (IGZO).

In some embodiments, the thin film transistor further includes a gate dielectric layer 6 located between the gate layer 5 and the channel layer 4. Optional material for the gate dielectric layer 6 includes at least one of hafnium oxide, hafnium aluminum oxide, and aluminum oxide.

Compared with a transistor with FinFET architecture, a transistor with CAA architecture according to the present embodiment has the following characteristics.
1) Compared with a planar channel structure, a vertical channel structure reduces the horizontal area occupation of an electrode by stacking source/drain electrodes, which can significantly reduce the size of the transistor, and is conducive to reducing the density of the device unit. The length of the channel is determined by the thickness of the insulating layer 3, and the miniaturization of the length of the channel is not limited by the lithography process, which is conducive to achieving a smaller length of the channel, thereby increasing the width to length ratio of the channel, achieving a greater device current and reducing power consumption.
2) The CAA architecture with the annular channel surrounding the gate 5 can greatly increase the contact area between the gate 5 and the channel layer 4, thereby significantly enhancing the gate control ability of the gate 5 on the channel layer 4 and improving the current conduction efficiency. Compared with a GAA (Gate All Around) architecture, the CAA architecture also has a larger contact area between the gate 5 and the channel layer 4.

At the same time, in order to solve current problems of poor contact performance and poor conductivity of the source/drain electrodes of the transistor, the TFT transistor provided in this embodiment adopts a layered structure for the first source/drain layer 1 as follows.

The first source/drain layer 1 includes a first metal layer 11 and a second metal layer 12, the first metal layer 11 is close to the insulating layer 3, and the second metal layer 12 is away from the insulating layer 3. The material for the first metal layer 11 is a metal with a work function being lower than that of molybdenum. The material for the second metal layer 12 is a metal with a conductivity being higher than 3×10⁶ S/m and oxidation resistance not being lower than that of molybdenum.

Compared with the transistor of the FinFET architecture, the CAA transistor of the present embodiment also has the following characteristics after forming the source/drain electrodes in layers by using different metals.
3) The first metal layer 11 close to the insulating layer 3 adopts a metal with a lower work function, which can obtain better contact performance. Since a metal with a lower work function usually has weaker oxidation resistance, the second metal layer 12 away from the insulating layer 3 and close to a top channel region adopts a metal with better conductivity and better oxidation resistance. While protecting the first metal layer 11 from oxidation without reducing the contact performance, resistance of the source/drain metal lead is reduced, and conductivity of the transistor is improved.

When forming the first source/drain layer 1 in layers, optional material and thickness ratio of first metal layer 11 and the second metal layer 12 may adopt the following two schemes.

In the first scheme, thickness ratio of the first metal layer 11 to the second metal layer 12 is not less than 10, and the total thickness of the first metal layer 11 and the second metal layer 12 is not less than 50 nm.

Correspondingly, optional material for the first metal layer 11 is titanium (Ti) or tungsten (W), and optional material for the second metal layer 12 is silver (Ag) or gold (Au).

Specifically, the first metal layer 11 close to the insulating layer 3 adopts a metal with a lower work function and a higher conductivity, such as Ti and W, so as to obtain good contact performance and high conductivity. In order to ensure contact performance and conductivity, the first metal layer 11 is as thick as possible.

The second metal layer 12 is formed on an upper surface of the first metal layer 11, and a metal with stronger oxidation resistance, such as Ag and Au, is selected to prevent the first metal layer 11 with weak oxidation resistance from being oxidized. Since the second metal layer 12 only plays the role of anti-oxidation, the second metal layer 12 is relatively thin.

Through the material and thickness configuration between the first metal layer 11 and the second metal layer 12 in the first scheme, the transistor can have good contact performance, good conductivity and good oxidation resistance at the same time.

In the second scheme, thickness ratio of the first metal layer 11 to the second metal layer 12 is 0.9 to 1.1, and the total thickness of the first metal layer 11 and the second metal layer 12 is not less than 50 nm.

Correspondingly, the material for the first metal layer 11 is titanium (Ti) or tungsten (W), and the material for the second metal layer 12 is molybdenum (Mo) or titanium nitride (TiN).

Specifically, the first metal layer 11 is selected from a metal with a work function being lower than that of Mo, such as Ti, W and the like, so as to ensure better contact performance between the first source/drain layer 1 and the semiconductor, that is, the channel layer 4, and a relatively thick thickness can be adopted. The second metal layer 12 needs to have a lower work function, a higher conductance and a better oxidation resistance at the same time, such as TiN, Mo, etc. and the thicker the better. Therefore, in the second scheme, the thicknesses of the first metal layer 11 and the second metal layer 12 are equivalent, so that the characteristics of high conductivity and low contact resistance can be obtained at the same time.

In some embodiments, as shown in FIG. 2, the first source/drain layer 1 further includes a third metal layer 13, which is located between the first metal layer 11 and the insulating layer 3. A material for the third metal layer 13 is a metal with an oxidation resistance being not lower than that of molybdenum.

So far, the first metal layer 11, the second metal layer 12, and the third metal layer 13 form a first source/drain layer 1 of a three-layer sandwich structure. Herein, the second metal layer 12 is a top layer, and a metal such as Mo, TiN, Au, Ag, etc. can be selected to avoid the top of the first source/drain layer 1 being oxidized, which may lead to poor contact performance and increased metal wiring resistance. The first metal layer 11 is used as an intermediate layer or a sandwich layer, and a metal with a lower work function, such as Ti or W, can be selected to further improve the contact performance between the channel layer 4 and the first source/drain layer 1. The third metal layer 13 is a bottom layer close to the insulating layer 3, and a metal such as Mo, TiN, Au, Ag, etc. can be selected to protect the bottom of the first source/drain layer 1 from being oxidized, so as to avoid poor contact performance and increased metal wiring resistance.

Similar to the layered formation of the first source/drain layer 1, the second source/drain layer 2 can also adopt the same layered configuration. In some embodiments, as shown in FIG. 2, the second source/drain layer 2 includes a fourth metal layer 21, a fifth metal layer 22, and a sixth metal layer 23. The fourth metal layer 21 is close to the insulation layer 3, and the fifth metal layer 22 is away from the insulation layer 3. The sixth metal layer 23 is located between the fourth metal layer 21 and the insulation layer 3.

Specifically, the fifth metal layer 22 is the bottom layer of the second source/drain layer 2. Mo, TiN, Au, Ag or the like can be selected to avoid the bottom of the second sourc/drain layer 2 being oxidized, which may lead to poor contact performance and increased metal wiring resistance. The fourth metal layer 21 is used as an intermediate layer or a sandwich layer of the second source drain layer 2, and a metal with lower work function, such as Ti or W, can be selected to further improve the contact performance between the channel layer 4 and the second source/drain layer 2. The sixth metal layer 23 is a top layer of the second source drain layer 2 close to the insulation layer 3. Mo, TiN, Au, Ag or the like can be selected in order to protect the top of the second source drain layer 2 from oxidation and avoid the deterioration of contact performance and the increased metal wiring resistance.

Further, as shown in FIG. 2, the bottom of the gate 5 is located within the fourth metal layer 21, and a material for the fourth metal layer 21 is a metal with a work function being lower than that of molybdenum. By using the fourth metal layer 21 with a low work function to surround the bottoms of the gate 5 and the channel layer 4, contact performance can be further improved.

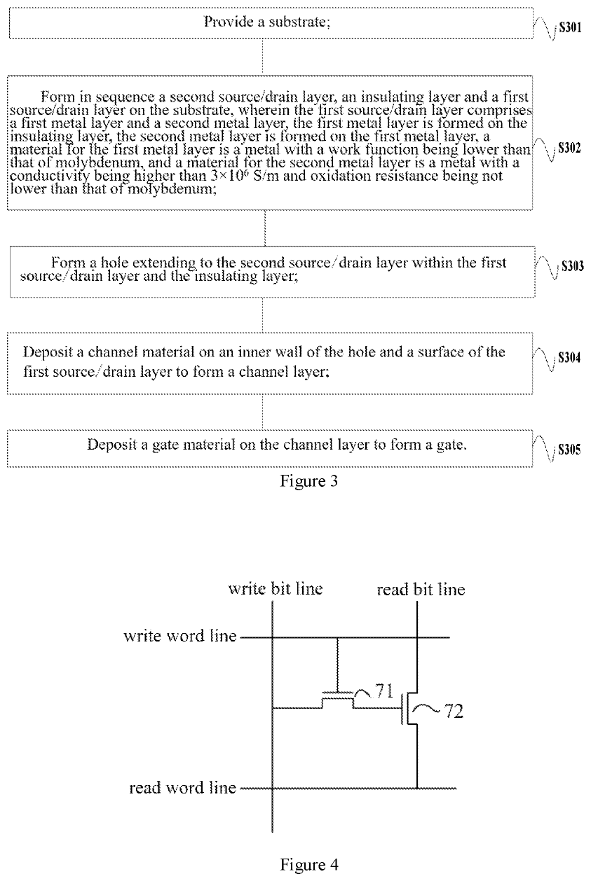

In a second aspect, as shown in FIG. 3, the present disclosure provides a method for preparing a thin film transistor including steps S301 to S305 as follows.

S301: Provide a substrate, where a silicon substrate may be used.

S302: Form in sequence a second source/drain layer 2, an insulating layer 3 and a first source/drain layer 1 on the substrate. Herein, the first source/drain layer 1 includes a first metal layer 11 and a second metal layer 12, the first metal layer 11 is formed on the insulating layer 3, and the second metal layer 12 is formed on the first metal layer 11. A material for the first metal layer 11 is a metal with a work function being lower than that of molybdenum. A material for the second metal layer 12 is a metal with a conductivity being higher than 3×10⁶ S/m and oxidation resistance being not lower than that of molybdenum.

Specifically, a pre-oxidation layer with a thickness of 300-400 nm can be deposited on the substrate first. After the deposition is completed, a pre-cleaning is performed, and then a metal material layer for forming the second source/drain layer 2 is deposited on the pre-oxidation layer as follows.

A pre-oxide layer is pre-cleaned. A source/drain metal material is deposited on the pre-cleaned pre-oxidation layer. A layered deposition method is adopted. The material for the fifth metal layer 22 such as Mo, TiN, Au, Ag, etc. is deposited for the first layer. A material for the fourth metal layer 21 such as Ti or W is deposited for the second layer. A material for the sixth metal layer 23 such as Mo, TiN, Au, Ag, etc. is deposited for the third layer.

Next, a double protection layer is deposited on the source/drain metal material layer, which can be a double protective layer formed by SiN and SiO, and the thickness of the double protective layer is about 200 nm. Next, the source/drain metal material layer is photolithographically processed. In particular, after the double protective layer is covered with the photoresist, exposure, development, and etching are performed in sequence to form a second source/drain layer 2.

Next, a fill oxide layer is deposited on the second source/drain layer 2, followed by chemical mechanical polishing and cleaning. After completion, an insulating layer material is deposited to form the insulating layer 3.

Next, the first source/drain layer metal is deposited on the insulating layer 3, and a layered deposition method is adopted. A material for the third metal layer 13 such as Mo, TiN, Au, Ag, etc. is deposited for the first layer. A material for the first metal layer 11 such as Ti or W is deposited for the second layer. A material for the second metal layer 12 such as Mo, TiN, Au, Ag, etc. is deposited for the third layer. Then, double protective layer deposition, covering of the photoresist, exposure, development, etching, and cleaning are performed in sequence to form the first source/drain layer 1.

S303: Form a hole extending to the second source/drain layer 2 within the first source/drain layer 1 and the insulating layer 3, where the required hole can be formed by deep etching as follows.

A fill oxide is deposited on the first source/drain layer 1 again, and then chemical mechanical polishing and cleaning are performed, and the polishing position stays on the filling oxide layer.

A through hole is formed as follows. A double protective layer (SiN+SiO) is deposited at the location where the through hole is to be formed, followed by covering of the photoresist, and then exposure, development, etching, cleaning and chemical mechanical polishing are performed, forming a through hole whose bottom reaches the first source/drain layer 1 and a through hole whose bottom reaches the second source/drain layer 2, respectively.

A channel hole is formed as follows. A double protective layer (SiN+SiO) is deposited at the location where the channel hole is to be formed, followed by covering of the photoresist. After aligning with the first source/drain layer 1, exposure, development, etching and cleaning are performed, forming a channel hole penetrating the first source/drain layer 1 and the insulating layer 3, whose bottom reaches the second source/drain layer 2.

S304: Deposit a channel material on an inner wall of the hole and a surface of the first source/drain layer 1 to form a channel layer 4.

S305: Deposit a gate material on the channel layer 4 to form a gate 5.

In some embodiments, after depositing the channel material, the gate dielectric material is first deposited to form the gate dielectric layer 6, and then the gate material is deposited on the surface of the gate dielectric layer 6.

The method for depositing the channel material, the gate material and the gate dielectric material in the channel hole can be atomic layer deposition.

In a third aspect, the present disclosure provides a memory including a plurality of memory arrays which include the thin film transistor provided in the first aspect.

FIG. 4 shows an alternative memory array structure of 2T0C in which one array includes two thin film transistors according to the embodiment of the present disclosure, i.e., a first thin film transistors 71 and a second thin film transistor 72. Herein, the gate of the first thin film transistor 71 is electrically connected to a write word line WWL, the source is electrically connected to a write bit line WBL, and the drain is electrically connected to the gate of the second thin film transistor 72. The source of the second thin film transistor 72 is electrically connected to a read word line RWL, and the drain is electrically connected to a read bit line RBL.

By applying the thin film transistor according to the embodiment of the present disclosure to the memory circuit of 2T0C, the gate of one TFT transistor can be directly connected to the source/drain of another TFT transistor, without the need for external lead, and thus the volume of the entire memory can be greatly reduced to facilitate further miniaturization of the memory.

In addition, the thin film transistor provided by the embodiments of the present disclosure can also be applied to a memory array of 1T0C, 1T1C, and 2T1C, which is not specifically limited herein.

In a fourth aspect, the present disclosure provides a display including a pixel circuit which includes the thin film transistor provided in the first aspect.

According to one or more embodiments of the present disclosure, the present disclosure has the following beneficial effects or advantages.

According to the present disclosure, there is provided a thin film transistor, a memory and a display. In the thin film transistor, a gate of the thin film transistor passes through a first source/drain layer and an insulating layer, and an annular channel surrounds the gate to form an architecture of Channel All Around (CAA), which is referred to as a transistor with CAA architecture. The transistor with CAA architecture according to the present disclosure has the following advantages compared to a transistor with FinFET architecture. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel layer, thereby significantly enhancing the control ability of the gate on the channel, and improving current conduction efficiency. Compared with the GAA (Gate All Around) architecture, the CAA architecture also has a larger contact area between the gate and channel. Thirdly, a layered structure is adopted for the first source/drain layer of the thin film transistor, in which the first metal layer close to the insulating layer adopts a metal with a lower work function to improve the contact performance. Since a metal with a lower work function usually have weaker oxidation resistance, the second metal layer away from the insulating layer adopts a metal with better conductivity and better oxidation resistance. While protecting the first metal layer from oxidation without reducing the contact performance, the resistance of the source/drain metal lead is reduced, and the conductivity of the transistor is improved.

Although the preferred embodiments of the present disclosure have been described, ordinary skill in the art can make additional changes and modifications to these embodiments once they learn the basic inventive concept. Therefore, the appended claims are intended to be interpreted as including the preferred embodiments and all changes and modifications falling within the scope of the present disclosure.

Obviously, those skilled in the art can make various modifications and variations to the present disclosure without departing from the spirit and scope of the present disclosure. In this way, if these modifications and variations of the present disclosure fall within the scope of the claims of the present disclosure and their equivalent technologies, the present disclosure also intends to include these modifications and variations.

1. A thin film transistor comprising:
a second source/drain layer, an insulating layer, and a first source/drain layer stacked in sequence; and
a gate and a channel layer surrounding the gate, which are located within the first source/drain layer and the insulating layer, wherein the channel layer is in contact with the first source/drain layer and the second source/drain layer,
wherein the first source/drain layer comprises a first metal layer and a second metal layer, the first metal layer is close to the insulating layer, the second metal layer is away from the insulating layer, the material for the first metal layer is a metal with a work function being lower than that of molybdenum, and the material for the second metal layer is a metal with a conductivity being higher than 3×106 S/m and an oxidation resistance being not lower than that of molybdenum.

2. The thin film transistor according to claim 1, wherein a ratio of a thickness of the first metal layer to a thickness of the second metal layer is not less than 10, and a total thickness of the first metal layer and the second metal layer is not less than 50 nm.

3. The thin film transistor according to claim 2, wherein a material for the first metal layer is tanium or tungsten, and a material for the second metal layer is silver or gold.

4. The thin film transistor according to claim 1, wherein a ratio of a thickness of the first metal layer to a thickness of the second metal layer is 0.9 to 1.1, and a total thickness of the first metal layer and the second metal layer is not less than 50 nm.

5. The thin film transistor according to claim 4, wherein a material for the first metal layer is titanium or tungsten, and a material for the second metal layer is molybdenum or titanium nitride.

6. The thin film transistor according to claim 1, wherein the first source/drain layer further comprises a third metal layer, the third metal layer is located between the first metal layer and the insulating layer, and a material for the third metal layer is a metal with an oxidation resistance being not lower than that of molybdenum.

7. The thin film transistor according to claim 1, wherein the second source/drain layer comprises a fourth metal layer, a fifth metal layer and a sixth metal layer, the fourth metal layer is close to the insulating layer, the fifth metal layer is away from the insulating layer, and the sixth metal layer is located between the fourth metal layer and the insulating layer.

8. A method for preparing a thin film transistor comprising:
providing a substrate;
forming in sequence a second source/drain layer, an insulating layer and a first source/drain layer on the substrate, wherein the first source/drain layer comprises a first metal layer and a second metal layer, the first metal layer is formed on the insulating layer, the second metal layer is formed on the first metal layer, a material for the first metal layer is a metal with a work function being lower than that of molybdenum, and a material for the second metal layer is a metal with a conductivity being higher than 3×106 S/m and oxidation resistance being not lower than that of molybdenum;
forming a hole extending to the second source/drain layer within the first source/drain layer and the insulating layer;
depositing a channel material on an inner wall of the hole and a surface of the first source/drain layer to form a channel layer; and
depositing a gate material on the channel layer to form a gate.

9. A memory comprising a plurality of storage arrays which comprise the thin film transistor according to claim 1.

10. A display comprising a pixel circuit which comprises the thin film transistor according to claim 1.
